(19) United States
(12) Patent Application Publication
(10) Pub. No.: US 2012/0036315 A1
(43) Pub. Date: Feb. 9, 2012

(54) Morphing Memory Architecture

(75) Inventors: William R. Reohr, Ridgefield, CT (US); Darren L. Anand, Williston, VT (US); Mark D. Jacunski, Colchester, VT (US)

(73) Assignee: International Business Machines Corporation, Armonk, NY (US)

(21) Appl. No.: 12/852,946

(22) Filed: Aug. 9, 2010

(51) Int. Cl. G06F 12/00; G11C 8/00; G11C 7/06

(52) U.S. Cl. 711/105; 365/210.1; 365/230.01; 365/149; 711/E12.001

(57) ABSTRACT

A memory circuit comprises a memory array including a plurality of memory cells, multiple word lines, and at least one bit line. Each of the memory cells is coupled to a unique pair of a bit line and a word line for selectively accessing the memory cells. The memory circuit further includes at least one control circuit coupled to the word lines and operative to selectively change an operation of the memory array between a first data storage mode and at least a second data storage mode as a function of at least one control signal supplied to the control circuit. In the first data storage mode, each of the memory cells is allocated to a corresponding stored logic bit, and in the second data storage mode, at least two memory cells are allocated to a corresponding stored logic bit.

### FIELD OF THE INVENTION

The present invention relates generally to the electrical, electronic, and computer arts, and more particularly relates to memory systems.

### BACKGROUND OF THE INVENTION

With reference to FIG. 1, a conventional one-transistor, one-capacitor (1T1C) memory cell 100 is shown that forms part of an array of such cells in a typical dynamic random access memory (DRAM) integrated circuit (IC) memory. Memory cell 100 includes an access transistor M1 for reading data from or writing data to a storage capacitor C1. A first source/drain of transistor M1 is coupled to a corresponding bit line BL, a second source/drain of transistor M1 is coupled to capacitor C1 at node N1, and a gate of transistor M1 is coupled to a corresponding word line WL. A second terminal of capacitor C1 is connected to ground. Only one memory cell, one word line, and one bit line are shown, although a plurality of word lines, bit lines, and memory cells arranged in rows and columns are generally used in a typical DRAM array. In terms of density, an array of 1T1C memory cells of the type shown in FIG. 1 is preferred since these cells provide a single data bit for a relatively small amount of IC die area.

With reference now to FIG. 2, a two-transistor, two-capacitor (2T2C) memory cell 200 is shown that forms part of an array of such cells in a DRAM IC memory. Memory cell 200 includes two access transistors, M1 and M2, for reading data from or writing data to storage capacitors, C1 and C2, respectively. A first source/drain of transistor M1 is coupled to a first bit line BL, a second source/drain of transistor M1 is coupled to capacitor C1 at node N1, and a gate of transistor M1 is coupled to a word line WL. A first source/drain of transistor M2 is coupled to a complementary bit line ˜BL, a second source/drain of transistor M2 is connected to capacitor C2 at node N2, and a gate of transistor M2 is also coupled to a word line WL. Only two memory cells, a word line, and two bit lines are shown, although a plurality of word lines, bit lines, and 2T2C memory cells arranged in rows and columns may be used in a typical DRAM array. In terms of IC density, an array of 2T2C memory cells of the type shown in FIG. 2 is generally not preferred, since these cells provide only a single data bit for twice the amount of IC die area compared to an array employing 1T1C cells. In some applications, however, certain advantages can be achieved using 2T2C cells, such as, for example, greater noise immunity and low energy operation, among other concomitant advantages, which makes such cells more desirable than 1T1C cells.

### SUMMARY OF THE INVENTION

Principles of the invention provide a memory architecture for use, for example, in an embedded DRAM application. Advantageously, embodiments of the invention provide a mechanism for use in a memory array which enables one or more memory cells in the memory array to dynamically switch between two or more functional modes of operation (e.g., a half-capacity state and a full-capacity state), referred to herein as “morphing memory,” depending upon one or more characteristics of the memory array (e.g., operational voltage, temperature, etc.). In this manner, the novel memory architecture is able to achieve benefits of either type of memory operation depending upon the application in which the memory array is being used at any given time.

In accordance with one aspect of the invention, a memory circuit comprises a memory array including a plurality of memory cells, multiple word lines, and at least one bit line. Each of the memory cells is coupled to a unique pair of a bit line and a word line for selectively accessing the memory cells. The memory circuit further includes at least one control circuit coupled to the word lines and operative to selectively change an operation of the memory array between a first data storage mode and at least a second data storage mode as a function of at least one control signal supplied to the control circuit. In the first data storage mode, each of the memory cells is allocated to a corresponding stored logic bit, and in the second data storage mode, at least two memory cells are allocated to a corresponding stored logic bit.

In accordance with another aspect of the invention, a memory circuit for use in a processing system comprises a memory array including a plurality of memory cells, at least one bit line, and at least two word lines, each memory cell being coupled to a unique pair of a bit line and a word line, each word line being adapted for accessing at least one of two memory cells connected to the at least one bit line. The memory circuit further includes first and second control circuits. The first control circuit is operative to enable one of the word lines in a first operational mode of the memory circuit and to enable at least two of the word lines in a second operational mode of the memory circuit. The second control circuit is operative to adapt the processing system to selectively transition at least a portion of the memory array between the first and second operational modes. In the first operational mode, each of the memory cells is allocated to a corresponding stored logic bit, and in the second operational mode, at least two memory cells are allocated to a corresponding stored logic bit.

In accordance with yet another embodiment of the invention, a circuit is provided for use in conjunction with a DRAM comprising at least one differential sense amplifier and a memory array including a plurality of memory cells and at least first and second word lines coupled to the memory cells, the first word line being operative for selectively accessing a first one of the memory cells coupled to a first input of the sense amplifier and the second word line being operative for selectively accessing a second one of the memory cells coupled to a second input of the sense amplifier. The circuit includes a first controller coupled to the memory array and operative, during a given memory cycle, to selectively enable one word line in a first operational mode of the circuit or to selectively enable at least two word lines in at least a second operational mode of the circuit. The circuit further includes a second controller operative to adapt the DRAM to operate with the memory array in the first and second operational modes.

In accordance with still another embodiment of the invention, a method is provided for dynamically transitioning a memory circuit between a first data storage mode and at least a second data storage mode, the memory circuit comprising at least one differential sense amplifier and a memory array including a plurality of memory cells and at least first and second word lines coupled to the memory cells, the first word line being operative for selectively accessing a first one of the memory cells coupled to a first input of the sense amplifier and the second word line being operative for selectively accessing a second one of the memory cells coupled to a second input of the sense amplifier. The method comprises the steps of: receiving a request for a change in data storage mode of the memory array; determining whether the memory circuit is operative in one of at least a first data storage mode indicative of a full capacity state, wherein each of the memory cells in the memory array is allocated to a corresponding stored logic bit, and a second data storage mode indicative of a half capacity state, wherein at least two memory cells in the memory array are allocated to a corresponding stored logic bit; and changing memory status queues in the memory circuit to one of at least full capacity and half capacity states as a function of the selected data storage mode.

In accordance with another embodiment of the invention, a computer program product for dynamically transitioning a memory circuit between a first data storage mode and at least a second data storage mode is provided, the memory circuit comprising a memory array including a plurality of memory cells and at least first and second word lines coupled to the memory cells for selectively accessing one or more of the memory cells. The computer program product includes: a computer readable storage medium; first program instructions to receive a request for a change in data storage mode of the memory array; second program instructions to determine whether the memory circuit is operative in one of at least a first data storage mode indicative of a full capacity state, wherein each of the memory cells in the memory array is allocated to a corresponding stored logic bit, and a second data storage mode indicative of a half capacity state, wherein at least two memory cells in the memory array are allocated to a corresponding stored logic bit; and third program instructions to change memory status queues in the memory circuit to one of at least full capacity and half capacity states as a function of the selected data storage mode. The first, second and third program instructions are stored on said computer readable storage medium.

These and other features, objects and advantages of the present invention will become apparent from the following detailed description of illustrative embodiments thereof, which is to be read in conjunction with the accompanying drawings.

### BRIEF DESCRIPTION OF THE DRAWINGS

The following drawings are presented by way of example only and without limitation, wherein:

FIG. 1 is a schematic diagram depicting a conventional 1T1C memory cell suitable for use in a single-cell storage DRAM architecture;

FIG. 2 is a schematic diagram depicting a conventional 2T2C memory cell suitable for use in twin-cell storage DRAM architecture;

FIG. 3 is a block diagram depicting at least a portion of an exemplary processing system comprising memory adapted for operation in at least a full capacity state or a half capacity state, according to an embodiment of the present invention;

FIG. 4A is a block diagram depicting at least a portion of an exemplary DRAM array comprising a differential sense amplifier and operative in full capacity and half capacity modes, according to an embodiment of the invention;

FIG. 4B is a block diagram depicting at least a portion of an exemplary DRAM array comprising a single-ended sense amplifier operative in full and half capacity modes, according to an embodiment of the invention;

FIG. 4C is a block diagram depicting at least a portion of an exemplary DRAM array in which 1T1C cells having both N-type and P-type access transistors are connected by a common bit line to a sense amplifier, according to an embodiment of the invention;

FIG. 5 is a schematic diagram depicting at least a portion of an exemplary memory circuit including logic circuitry for controlling operational states of memory cells in the memory array, according to an embodiment of the invention;

FIG. 6 is a flow diagram depicting at least a portion of an exemplary method for controlling a transition of memory cells between full capacity and half capacity operational modes, according to an embodiment of the invention;

FIGS. 7A-7C are timing diagrams depicting exemplary waveforms corresponding to the memory circuit shown in FIG. 5 during various operational modes of the memory circuit, according to embodiments of the invention;

FIG. 8 is a block diagram conceptually illustrating at least a portion of an exemplary memory system comprising a memory array operative to reorganize memory for the system by circulating data within data and address flows, and by storing the data in a new location(s) during a transition from full capacity to half capacity operational modes, according to an embodiment of the invention;

FIG. 9 is a timing diagram depicting exemplary waveforms corresponding to a timing adjustment for single-cell and twin-cell modes of operation, according to an embodiment of the invention; and

FIG. 10 is a block diagram depicting an exemplary methodology for adjusting word line voltage high level for single-cell and twin-cell modes of operation, according to an embodiment of the invention.

It is to be appreciated that elements in the figures are illustrated for simplicity and clarity. Common but well-understood elements that may be useful or necessary in a commercially feasible embodiment may not be shown in order to facilitate a less obstructed view of the illustrated embodiments.

### DETAILED DESCRIPTION OF PREFERRED EMBODIMENTS

Principles of the present invention will be described herein in the context of illustrative embodiments of a memory architecture suitable for use in a dynamic random access memory (DRAM), embedded or discrete. It is to be appreciated, however, that the invention is not limited to the specific apparatus and methods illustratively shown and described herein. Rather, aspects of the invention are directed broadly to techniques for use in a memory circuit, such as, for example, embedded DRAM, which enable one or more memory cells in the memory circuit to dynamically switch between a plurality of modes of operation (e.g., a half-capacity state and a full-capacity state) as a function of one or more characteristics of the memory array (e.g., operational voltage, temperature, etc.). A memory circuit operative to perform techniques of the invention may be referred to herein as “morphing memory.” In this manner, the novel memory architecture can adapt the operational mode of its memory cells to the application in which the memory circuit is being used at any given time to thereby achieve benefits of each type of memory architecture.

It will become apparent to those skilled in the art given the teachings herein that numerous modifications can be made to the embodiments shown that are within the scope of the present invention. That is, no limitations with respect to the specific embodiments described herein are intended or should be inferred.

Memory circuits may be fabricated by semiconductor processing, such as, for example, bulk silicon or silicon-on-insulator (SOI) semiconductor fabrication. Such semiconductor fabrication methodologies are well-known in the art. Embedded memories may be fabricated by semiconductor processing technologies used to fabricate logic devices and logic circuits. Such semiconductor processing technologies may be referred to as logic fabrication technologies. Some, but not necessarily all, embedded memories may require processing steps in substitution for, or in addition to, those processing steps required by logic fabrication technologies. For example, forming DRAM cells may require extra processing steps known to those skilled in the art. Logic fabrication technologies may be known by their lithographic dimensions. Such logic fabrication technologies, for example, 45-nanometer (nm) or 32-nm technologies, may be used to fabricate memory circuits according to embodiments of the invention.

Although reference may be made herein to n-channel metal-oxide-semiconductor (NMOS) or p-channel metal-oxide-semiconductor (PMOS) field-effect transistor (FET) devices which may be formed using a complementary metal-oxide-semiconductor (CMOS) IC fabrication process, the invention is not limited to such devices and/or such an IC fabrication process. Furthermore, although preferred embodiments of the invention may be fabricated in a silicon wafer, embodiments of the invention can alternatively be fabricated in wafers comprising other materials, including but not limited to gallium arsenide (GaAs), indium phosphide (InP), etc.

Aspects of the present invention advantageously provide a memory circuit, or components thereof, having improved performance and reliability. The memory circuit may comprise, for example, an embedded memory (e.g., a memory embedded within an IC) or a stand-alone (e.g., discrete) memory (e.g., a memory that is the primary component within an IC). The memory is preferably a DRAM. Memories and their associated memory cells may be comprised of various types, including, but not limited to, volatile, nonvolatile, static, dynamic, read only, random access, flash, one-time programmable, multiple-time programmable, magnetoresistive phase-change memory (PCM), etc. Embedded memories are incorporated within a larger functional block, generally termed a logic circuit, for example, a microprocessor, a digital processing device, a field programmable gate array (FPGA), an application-specific integrated circuit (ASIC), etc.

A morphing DRAM architecture according to aspects of the invention advantageously enables a DRAM to transition between single-cell storage and twin-cell storage (per bit) for an infinitesimally small memory array cost and system micro-architecture cost. For example, the area overhead on an illustrative embedded DRAM is below about 0.1 percent, and the area impact on commodity DRAM is expected to be even lower (primarily because commodity DRAM does not require a reference cell, as will be explained in further detail herein below). A system designer can harness and blend advantages of both single-cell and twin-cell storage in an architectural solution and thereby realize a general purpose high capacity and/or low energy memory solution, respectively, that optimizes energy and performance on-the-fly for constantly shifting “working sets” (i.e., footprints of instructions and data stored) in a cache memory, for example.

Single-cell storage provides, for example, a higher capacity memory, in comparison to other memory architectures, such as, for example, twin-cell storage, but constrains a minimum allowable voltage. For example, embedded DRAM macros offering single-cell storage often require an additional power source and additional voltage islands beyond those required to support other logic and I/O circuits on the chip. Moreover, the DRAM macros require level shifters to move between the power domains. Both the macro design and the integration problems are complex. The inclusion of additional power source and additional voltage islands can be beneficially avoided, according to aspects of the invention, by switching to twin-cell storage once the voltage drops below a minimum voltage specified for single-cell operation.

By contrast, twin-cell storage offers several advantages. Prominent among these advantages include, but are not limited to: (i) low voltage storage is limited only by surrounding logic and latches; (ii) the potential to operate at nearly half the random access cycle time; (iii) lower bit line and node voltages, and consequently longer data retention times; and (iv) true differential state storage with increased noise margin and resulting insensitivity to ripples on voltage supplies.

FIG. 3 is a block diagram depicting at least a portion of an exemplary processing system 300 comprising memory 302 adapted for operation in at least a full capacity state or a half capacity state, according to an embodiment of the invention. The processing system 300 may also include other memory 304 that is not operative to change capacity states. Thus, memory 302 and, optionally, other memory 304, together, may form an overall memory array in the processing system 300.

Processing system 300 further includes a memory controller 306 operative to selectively enable (i.e., control) whether the memory 302, or individual portions thereof, is functioning in full capacity or half capacity modes at any given time based at least in part on one or more control signals indicative of detected characteristics of the processing system 300. One or more sensors 308 may be operative to detect such characteristics (e.g., prescribed environmental and/or system variations; process, supply voltage and/or temperature (PVT) variations), and to generate the one or more control signals indicative thereof which are utilized by the memory controller 306. Processing system 300 preferably further includes a processor 310 coupled to the memory controller 306 and operative to adapt to a restriction in memory capacity resulting from a change in operational mode of the memory 302.

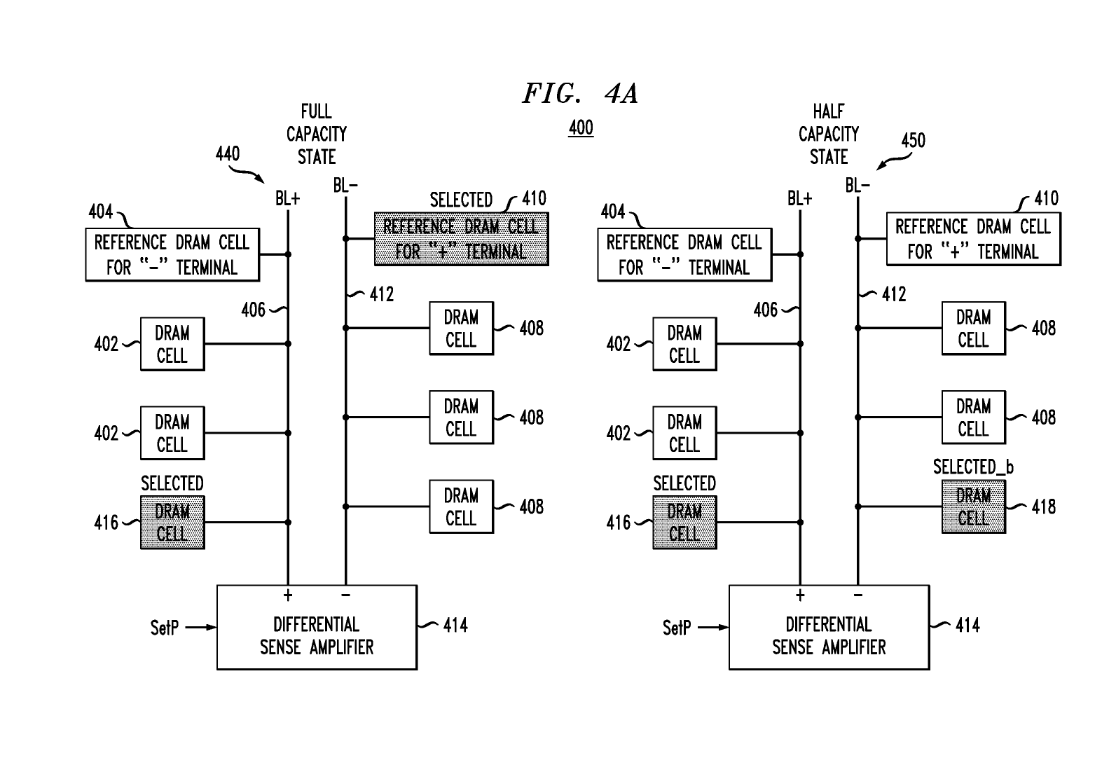

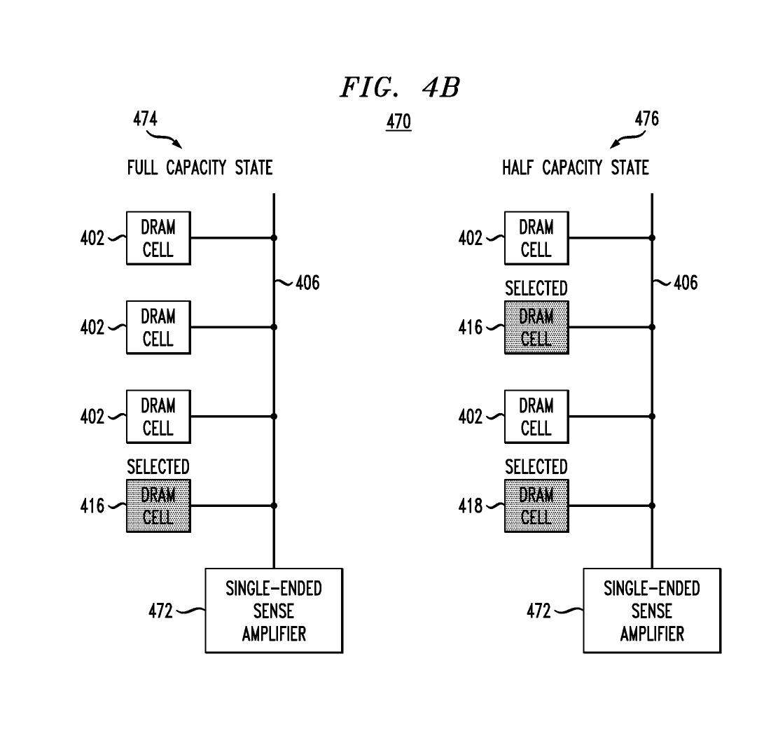

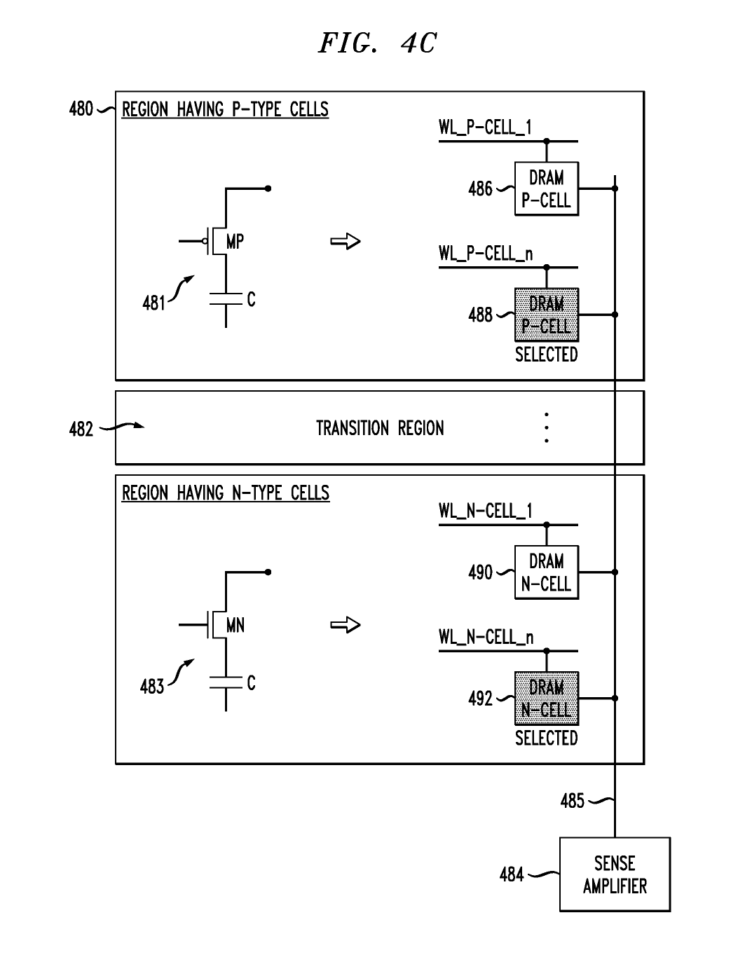

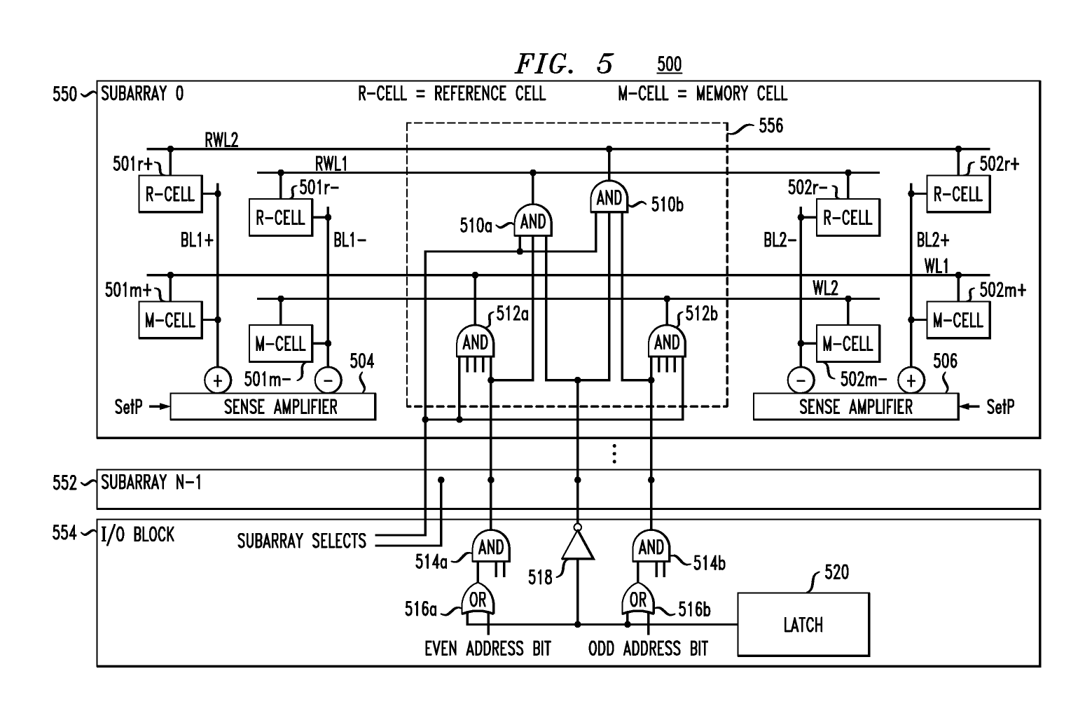

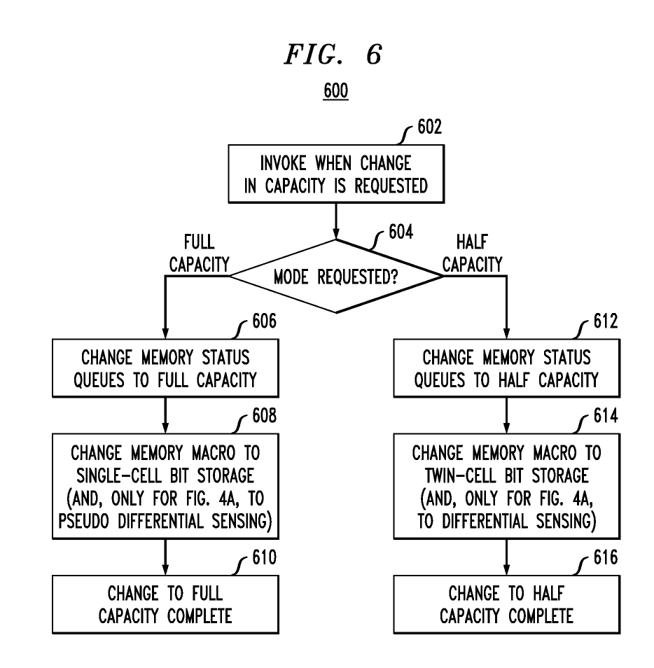

FIG. 4A is a block diagram depicting at least a portion of an exemplary DRAM array 400 operative in at least full capacity and half capacity modes, according to an embodiment of the invention. The term “mode” as used herein is intended to refer broadly to a designated functional state or manner of acting of a memory cell or cells; the term “state” may be used interchangeably herein with the term “mode.”

As shown in FIG. 4A, the exemplary DRAM array 400 comprises a first plurality of DRAM cells 402 and a first reference DRAM cell 404 coupled to a first bit line (BL+) 406. Likewise, DRAM array 400 includes a second plurality of DRAM cells 408 and a second reference DRAM cell 410 coupled to a second bit line (BL−) 412, which may be a complement of the first bit line 406. DRAM array 400 further includes a differential sense amplifier 414 coupled to bit lines 406 and 412. Specifically, a first node of sense amplifier 414, which may be a “+” (true) node, is connected to the first bit line 406, and a second node of the sense amplifier, which may be a “−” (complement) node, is connected to the second bit line 412.

In a first operational mode, which may be a full capacity state 440, a single DRAM cell 416 is selected for reading. When selected, the charge stored in DRAM cell 416 is transferred to corresponding bit line 406 and is received at the first (“+”) node of sense amplifier 414. Concurrently, the reference DRAM cell 410 coupled to the bit line opposite the selected DRAM cell 416 (namely, bit line 412) is selected. The charge stored in the selected reference DRAM cell is thus transferred to bit line 412 and is received at the second (“−”) node of sense amplifier 414. Hence, the voltage stored in the selected DRAM cell 416 is compared against the voltage stored in the reference DRAM cell 410 and if this voltage is above the reference DRAM cell voltage, the sense amplifier 414 is preferably operative to generate an output signal indicative of DRAM cell 416 being in a first logic state, which may be a physical “1” data state. Similarly, when it is determined that the selected DRAM cell voltage is below the reference DRAM cell voltage, the sense amplifier 414 is operative to generate an output signal indicative of DRAM cell 416 being in a second logic state, which may be a physical “0” data state. Thus, in the full capacity state, a single DRAM cell is used to store a single data bit (datum).

Reference cell 410 is also selected in combination with other memory cells 402 coupled to bit line 406 to assist in the evaluation of the data states stored in those other memory cells 402. It is to be appreciated that if a DRAM cell (e.g., cell 408) coupled to bit line 412 is selected, reference DRAM cell 404 coupled to bit line 406, opposite bit line 412, would be concurrently selected for comparison against the selected DRAM cell for evaluation of the data state stored in the selected DRAM cell.

As known in the art, commodity DRAM does not typically employ a reference cell. Instead, a bit line precharge operation generally defines a prescribed reference level to which a selected memory cell (e.g., DRAM cell 416) is compared to ascertain its state. Hence, in a single-cell mode of operation (e.g., using 1T1C cells), it is contemplated that DRAMs having differential sense amplifiers can be constructed and operated without reference cells 404 and 410.

In a second operational mode, which may be a half capacity state 450, reference DRAM cells 404 and 410 are not selected. Rather, in this operational mode, two DRAM cells, 416 and 418, are selected for reading. More particularly, DRAM cell 416 is selected and DRAM cell 418, storing a complement state to DRAM cell 416, is concurrently selected (i.e., within the same memory cycle). When selected, the charge stored in DRAM cell 416 is transferred to corresponding bit line 406 and is received at the first (“+”) node of sense amplifier 414. Concurrently, complement DRAM cell 418 coupled to the bit line opposite DRAM cell 416 (namely, bit line 412) is selected. The charge stored in DRAM cell 418 is thus transferred to bit line 412 and is received at the second (“−”) node of the sense amplifier 414.

Hence, the voltage stored in the first selected DRAM cell 416 is compared against the voltage stored in the second selected DRAM cell 418, and if the voltage stored in the first selected DRAM cell is above the second selected DRAM cell voltage, sense amplifier 414 is operative to generate an output signal indicative of DRAM cell 416 being in a first logic state, which may be a physical “1” data state. Similarly, when it is determined that the first selected DRAM cell voltage is below the second selected DRAM cell voltage, sense amplifier 414 is operative to generate an output signal indicative of DRAM cell 416 being in a second logic state, which may be a physical “0” data state. Thus, although the reference DRAM cells 404 and 410 are not employed in the half capacity state 450, two DRAM cells are used to store a single data bit (datum).

As known in the art, a control signal, SetP, is preferably used to set the sense amplifier 414; in other words, to assist in the detection of the state on the bit lines. In particular, for DRAM, the sense amplifier 414, in conjunction with signal SetP, is operative as a latch which regenerates the signals for write-back of data to the DRAM cells. By way of illustration only, when it is determined that the voltage on bit line 406 is higher than the voltage on bit line 412, the sense amplifier 414 preferably sets the voltage on bit line 406 to VDD, or an alternative high voltage source (e.g., 1.0 volt), and sets the voltage on bit line 412 to ground, or an alternative low voltage source (e.g., 0 volt). Alternatively, when it is determined that the voltage on bit line 406 is lower than the voltage on bit line 412, the sense amplifier 414 preferably sets the voltage on bit line 406 to ground, or an alternative low voltage source (e.g., 0 volt), and sets the voltage on bit line 412 to VDD, or an alternative high voltage source (e.g., 1.0 volt).

The foregoing discussion has focused on the retrieval of state from the DRAM cells; essentially, the read operation. It should also be understood, however, that a write operation typically involves operational procedures that are identical (or nearly so) to a read operation, including activation of the SetP signal. In addition, the selected bit lines are driven to new states by dedicated write ports connected to them. The new states are transferred through the bit lines and into the selected memory cells. The need to trigger SetP during a write operation in a manner consistent to that used during a read operation is driven by the requirement that the charge in half-selected memory cells—those cells not selected for a write operation, but connected to the selected word line—must be restored.

FIG. 4B is a block diagram depicting at least a portion of an exemplary DRAM array 470 comprising a single-ended sense amplifier and operative in full capacity and half capacity modes, according to another embodiment of the invention. In this embodiment, a single-ended sense amplifier 472 is coupled to a bit line 406 having a plurality of DRAM cells 402 connected thereto. In a full capacity operational mode 474, a single DRAM cell 416 is selected during a given memory cycle. In a half capacity mode 476, at least two DRAM cells 416 and 418 coupled to the same bit line 406 are selected, the two cells storing a single data bit. Although not explicitly shown, it should be understood that single-ended sense amplifiers may also employ a SetP-like approach for detecting and regenerating state on the bit lines and within the memory cells. It will become apparent to those skilled in the art given the teachings herein that various configurations of DRAMs having single-ended sense amplifiers may be used with the techniques of the invention, according to various alternative embodiments thereof, and that these alternative embodiments are within the scope of the present invention.

FIG. 4C is a block diagram depicting at least a portion of an exemplary DRAM array 480 in which 1T1C cells 486, 488, 490, 492, having both N-type and P-type access transistors are connected by a common bit line 485 to a sense amplifier 484, according to an embodiment of the invention. Advantageously, N-type access transistors, MN, and P-type access transistors, MP, and their associated storage capacitors, C, which together form the respective 1T1C cells, are preferably arranged into N-type regions 483, comprising N-type DRAM cells 490 and 492, and P-type regions 481 of P-type cells 486 and 488 in DRAM array 480 to realize a compact physical IC design. A transition region 482 between designated regions 481, 483 of N-type and P-type cells may be required as a result of technology-driven ground rules that require a certain minimum spacing between N-type and P-type transistors. The exemplary DRAM array 480 shown in FIG. 4C is operative in low energy and high voltage modes.

To achieve lower energy operation (e.g., a low-energy mode of operation), the memory must be operated at low voltages, which may require the use of a 2T2C architecture having both an N-type DRAM cell and a P-type DRAM cell. By way of example only, with reference to FIG. 4C, both an N-type DRAM cell 492 and a P-type DRAM cell 488 coupled to the same bit line 485 are concurrently selected for this type of twin-cell storage so that the cells, collectively, easily store GND level voltages, corresponding to a physical “0” data state, and VDD level voltages, corresponding to a physical “1” data state. Selecting an N-type memory cell involves driving its corresponding word line from a low voltage, corresponding to an idle (e.g., standby) state of the memory cell, to a high voltage, corresponding to the selected state of the memory cell. Likewise, selecting a P-type memory cell involves driving its corresponding word line from a high voltage, corresponding to an idle state of the memory cell, to a low voltage, corresponding to the selected state of the memory cell.

To achieve lower energy operation at high voltage, it is desirable to operate the memory array 480 with only one 1T1C memory cell selected, either an N-type cell or a P-type cell, in order to minimize the charging and discharging of capacitance associated with the additional cells.

Unlike the illustrative embodiments of a memory array shown in FIGS. 4A and 4B, memory capacity does not change between modes of operation in the memory array 480 depicted in FIG. 4C.

FIG. 5 is a schematic diagram depicting at least a portion of an exemplary memory circuit 500 including logic circuitry for controlling operational states of memory cells in the memory array, according to an embodiment of the invention. The beneficial concepts of memory circuit 500 may be used in conjunction with general DRAM cells without a reference cell, the architectures of which are shown in FIGS. 4B and 4C. Memory circuit 500 preferably includes a plurality (e.g., n) of memory subarrays, namely, subarray 550 through subarray 552 (i.e., subarrays 0 to n−1, where n is an integer greater than 1) coupled to an input/output (I/O) block 554. The memory subarrays 550, 552 essentially comprise the core circuitry (e.g., memory cells, sense amplifiers, word line drivers, etc.) in the memory circuit 500. The I/O block 554 comprises interface logic (e.g., latches and other peripheral circuitry, etc.) used to drive or otherwise interface with the subarrays.

Each of the memory subarrays 550, 552 are coupled to I/O block 554 which includes circuitry operative to control transitioning of one or more selected memory cells in the subarrays from a first operational mode (e.g., half capacity state) to a second operational mode (e.g., full capacity state), as will be described in further detail below. Although at least a portion of the circuitry in only subarray 550 is shown, it is to be understood that the remaining subarrays (e.g., subarray 552) in memory circuit 500 will include similar circuitry.

With reference to FIG. 5, details of subarray 550 will now be described. More particularly, subarray 550 includes a plurality of reference cells (R-cells) 501r+, 501r−, 502r+ and 502r−, and a plurality of memory cells (M-cells) 501m+, 501m−, 502m+ and 502m−. Each of the reference cells and memory cells is coupled to a unique pair of bit and word lines. For example, reference cell 501r− is coupled to a first bit line BL1− and a first word line RWL1, which may be a reference word line, reference cell 501r+ is coupled to a second bit line BL1+ and a second word line RWL2, which may be a reference word line, reference cell 502r− is coupled to a third bit line BL2− and the first word line RWL1, and reference cell 502r+ is coupled to a fourth bit line BL2+ and the second word line RWL2. Likewise, memory cell 501m+ is coupled to the second bit line BL1+ and a third word line WL1, which may be a standard word line, memory cell 501m− is coupled to the first bit line BL1− and a fourth word line WL2, which may be a standard word line, memory cell 502m+ is coupled to the fourth bit line BL2+ and the third word line WL1, and memory cell 502m− is coupled to the third bit line BL2− and the fourth word line WL2.

The subarray 550 further includes a plurality of sense amplifiers, each sense amplifier being coupled to a corresponding plurality of reference and memory cells. Specifically, a first sense amplifier 504 includes a first node (e.g. terminal, input, etc.), which may be a positive (“+”) or true node, connected to the second bit line BL1+, and a second node, which may be a negative (“−”) or complement node, connected to the first bit line BL1−. A second sense amplifier 506 includes a first node, which may be a positive (“+”) or true node, connected to the fourth bit line BL2+, and a second node, which may be a negative (“−”) or complement node, connected to the third bit line BL2−. Each of the sense amplifiers 504, 506 preferably includes a control input for receiving a control signal, SetP, which enables the sense amplifier to function as a latch for regenerating the signals on the corresponding bit lines for the respective DRAM cells coupled thereto, as previously described.

It is to be appreciated that although only two sense amplifiers are shown in memory circuit 500, the invention is not limited to any specific number of sense amplifiers. Moreover, although each sense amplifier is shown having only two memory cells and two reference cells connected thereto, the invention is not limited to any specific number of memory cells and reference cells, nor is each sense amplifier required to have the same number of memory cells and/or reference cells coupled thereto. Other arrangements of the memory circuit that are within the scope of the present invention will become apparent to those skilled in the art given the teachings herein.

Due primarily to the number of memory cells and/or reference cells coupled to the bit lines in the memory circuit 500, there will inherently be a large capacitance on the negative and positive nodes of the sense amplifiers 504, 506. Prior to a read operation, the bit lines BL1+, BL1−, BL2−, BL2+, will preferably be charged to a prescribed voltage level (e.g., VDD/2), such as, for example, via a precharge circuit (not explicitly shown) or alternative mechanism. The capacitance on the positive and negative nodes helps to retain the bit lines at their precharged voltage levels.

When a given memory cell (e.g., memory cell 501m+, 501m−, 502m+, 502m−) is selected for a read operation, the selected cell either pulls the bit line to which it is connected above or below the prescribed precharge voltage level, depending on the stored state of the cell. For example, if a given memory cell to be read is storing a logic “1” state (e.g., VDD), when the given cell is selected for a read, the charge stored therein is transferred onto the corresponding bit line and the bit line is pulled above its precharge voltage level of VDD/2 (e.g., settling somewhere between VDD and VDD/2). Likewise, if the given memory cell to be read is storing a logic “0” state (e.g., ground or 0 volt), when the given cell is selected for a read, the charge stored therein is transferred onto the corresponding bit line and the bit line is pulled below its precharge voltage level of VDD/2 (e.g., settling somewhere between VDD/2 and zero volts). This differential signal can be sensed by the sense amplifier to generate an output signal indicative of the state stored in the memory cell. Consequently, a reference cell is not required in this case.

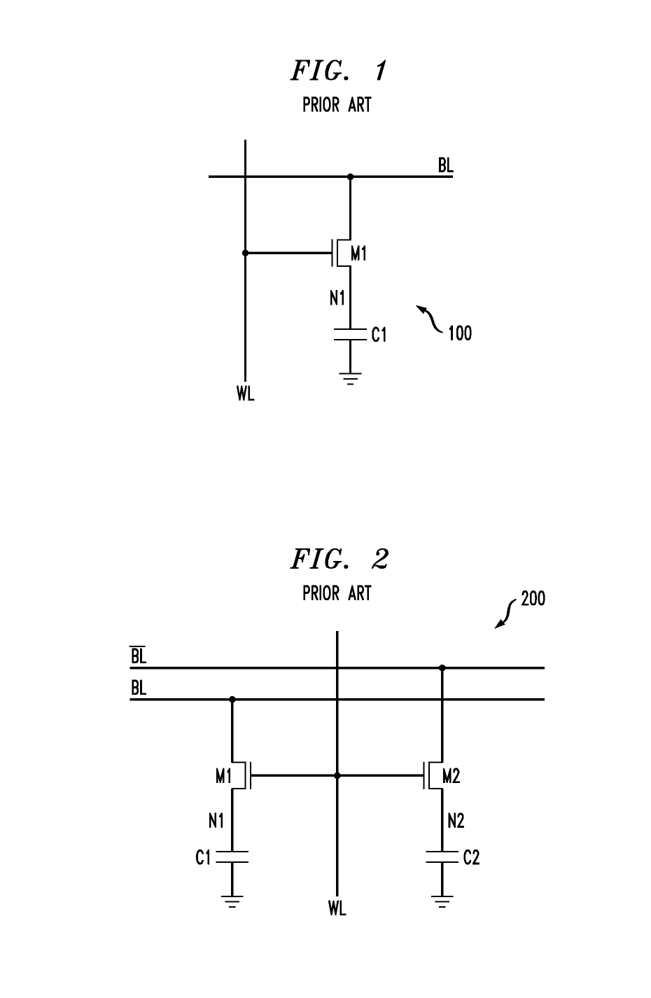

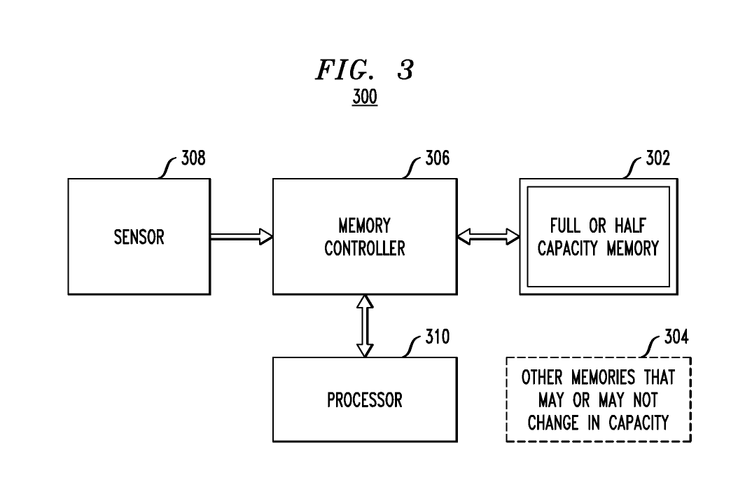

In terms of charge stored in a memory cell, which is indicative of the cell state, when the memory circuit 500 is operated in a full capacity (i.e., single-cell) mode, wherein a single memory cell is used to store one data bit (datum), the maximum charge ideally would be VDD times the capacitance of the cell storage capacitor, denoted C1 in FIG. 1, where VDD is a voltage supply level of the memory circuit. By comparison, when the memory circuit 500 is operated in a half capacity (i.e., twin-cell) mode, wherein two memory cells are used to store one datum, the charge stored in the memory cell, which is indicative of the cell state, ideally would be VDD times the sum of the capacitance of both storage capacitors, denoted C1 and C2 in FIG. 2.

The charge stored in the twin-cell configuration is essentially twice that of the single-cell configuration, and hence the twin-cell configuration can be operated at half the voltage of the single-cell configuration and still achieve the same signal charge as the single-cell configuration. That being said, the storage density of the twin-cell configuration is half that of the single-cell configuration. Hence, there are certain trade-offs between a memory circuit operated in a single-cell (full capacity) mode versus a memory circuit operated in a twin-cell (half capacity) mode.

More particularly, a half capacity memory design is advantageous, compared to a full capacity design, when the memory circuit is to be operated at lower voltages. Operation at lower voltages is often desired in order to reduce energy consumption in the memory circuit. The concept of voltage scaling seeks to capitalize on this concept of reducing energy consumption by reducing operating voltage in the circuit. By way of example only, operating the memory circuit at half the voltage results in a reduction in energy consumption by about a factor of six, which is highly desirable. Energy consumption per operation scales approximately as voltage to the power of 2.5 (i.e., V^{2.5}).

Each of the memory subarrays (e.g., subarray 550) further includes a controller 556 operative to receive one or more control signals (e.g., from the I/O block 554) and to facilitate a transition of one or more memory cells in the subarray from a first operational mode (e.g., half capacity state) to a second operational mode (e.g., full capacity state) as a function of the control signal(s). In the illustrative embodiment shown, the controller 556 includes a first functional AND gate 510a, a second functional AND gate 510b, a third functional AND gate 512a, and a fourth functional AND gate 512b. The first and second AND gates 510a, 510b are preferably operative to selectively disable the reference cells 501r+, 501r−, 502r−, 502r+ in subarray 550. The third and fourth AND gates 512a, 512b are preferably operative to perform a multi-select function in a decode path of the memory circuit 500 for selecting one or memory cells 501m+, 501m−, 502m−, 502m+ in subarray 550.

Specifically, a first input of AND gates 510a and 510b are coupled together and adapted to receive a first control signal, which may be a subarray select signal generated by I/O block 554, a second input of AND gate 510a is adapted to receive a second control signal, which may be a function of an even address bit signal, and a third input of AND gate 510a is connected to a second input of AND gate 510b and adapted to receive a third control signal. A third input of AND gate 510b is adapted to receive a fourth control signal, which may be a function of an odd address bit signal. An output of AND gate 510a is coupled to the first reference word line RWL1 and an output of AND gate 510b is coupled to the second reference word line RWL2. Thus, in order for the reference cells 501r+, 501r−, 502r−, 502r+ to be enabled, the first, second, third and fourth control signals should be a logic high (e.g., “1” or VDD) level.

AND gates 512a and 512b are preferably operative to select memory cells 501m+, 501m−, 502m−, 502m+. Each of AND gates 512a and 512b preferably includes n inputs, where n is an integer based at least in part on a number of subarrays (e.g., 550, 552) in memory circuit 500. Thus, the first n−1 inputs of AND gates 512a and 512b are adapted to receive the first control signal, which may be subarray select signals, the n^{th} input of AND gate 512a is adapted to receive the second control signal, and the n^{th} input of AND gate 512b is adapted to receive the fourth control signal. An output of AND gate 512a is coupled to the first word line WL1 for selecting memory cells 501m+ and 502m+, and an output of AND gate 512b is coupled to the second word line WL2 for selecting memory cells 501m− and 502m−. It is to be understood that alternative selection control circuitry suitable for use with the invention is contemplated, as will become apparent to those skilled in the art given the teachings herein.

At least a portion of the control signals used to selectively activate the reference and memory cells in the memory subarrays are generated by control signal generation circuitry in the I/O block 554. Specifically, the control signal generation circuitry, which is preferably connected in an address decode path of the memory circuit 500, comprises a first functional AND gate 514a, a second functional AND gate 514b, a first functional OR gate 516a, a second functional OR gate 516b, an inverter 518 and a latch 520, or alternative controller. AND gates 514a and 514b may already exist in a conventional I/O block used in the address decode path for selecting one of the plurality of memory subarrays. In I/O block 554, however, AND gates 514a and 514b do not directly receive the even address bit signal or the odd address bit signal, respectively. Rather, AND gates 514a and 514b are adapted to receive signals from OR gates 516a and 516b, respectively, inserted between AND gates 514a and 514b and their corresponding address bit control signals.

Specifically, OR gate 516a includes a first input adapted to receive the even address bit control signal, which may be presented to I/O block 554 or generated internally within the I/O block. Similarly, OR gate 516b includes a first input adapted to receive the odd address bit control signal, which may be presented to I/O block 554 or generated internally within the I/O block. Second inputs of OR gates 516a and 516b are connected together and adapted to receive an output signal generated by latch 520 for controlling the operational mode of one or more memory cells in the selected subarray. An output of OR gate 516a is connected to a first input of AND gate 514a, and an output of OR gate 516b is connected to a first input of AND gate 514b. An output of AND gate 514a is operative to generate the second control signal supplied to the memory subarrays, and an output of AND gate 514b is operative to generate the fourth control signal supplied to the memory subarrays. Inverter 518 includes an input connected to the output of latch 520 and an output operative to generate the third control signal supplied to the memory subarrays. All unspecified inputs to AND gates 510 through 514 shown in FIG. 5 are indicative of additional decode and/or control inputs used to select one or more word lines out of a plurality of word lines that would support the operational modes in the preceding discussion.

Latch 520 in I/O block 554 functions, at least in part, as a controller to determine whether the memory circuit 500 is operative in single-cell mode or in twin-cell mode, or any additional operational modes as may be included in other embodiments of the invention. In a twin-cell mode, latch 520 preferably generates an logic high output signal. Thus, latch 520, in conjunction with OR gates 516a and 516b and inverter 518, is operative to intervene and always drive a “true” (logic high) signal into the corresponding AND gates 514a, 514b. Likewise, the third control signal generated by inverter 518 will be a logic low level (e.g., 0 volt) in a twin-cell mode, thereby disabling the reference cells 501r+, 501r−, 502r−, 502r+ in subarray 550, which are not required for twin-cell operation.

With reference now to FIG. 6, a flow diagram is shown depicting at least a portion of an exemplary method 600 for controlling a transition of memory cells between full capacity and half capacity operational modes, according to an embodiment of the invention. Method 600 may be performed in a memory circuit, such as, for example, exemplary memory circuit 500 shown in FIG. 5, and represents a basic illustrative overview for implementing techniques of the invention.

Method 600 may be invoked, in step 602, when a change in operational mode of the memory circuit is requested. Once invoked, method 600 determines, in step 604, which operational mode is requested for the memory circuit. Although only two process flow branches are shown by way of example only for method 600, namely, a “full capacity” branch and a “half capacity” branch, according to other embodiments of the invention, more than two branches may be included, each branch corresponding to a distinct operational mode of the memory circuit.

In the illustrative case where the memory circuit is operative in full capacity or half capacity modes, when it is determined that full capacity mode is requested, method 600 proceeds to step 606, wherein memory status queues (e.g., cache memory), etc., in the memory circuit are changed from half capacity functionality to full capacity functionality. Thus, step 606 functions to convey to the overall memory system architecture information (e.g., memory size) which enables the system to adapt to the change in operational mode, since the manner in which the system stores data will change accordingly. In response, the system can then control the memory address space to adapt to the selected operational mode.

It is to be appreciated that, from a system level standpoint, the change in memory status queues, etc., does not generally involve preserving the state of the memory during the transition from one operational mode to another; i.e., while the memory structure is changed, the local state of the memory is not necessarily preserved. Thus, step 606 is also preferably operative to preserve or otherwise handle memory state locally, such as, for example, by storing the local data in another prescribed location in the memory, by rearranging data in the memory, by declaring local data in the memory invalid, etc. Other means of preserving memory state suitable for use with the present invention are contemplated, as will become apparent to those skilled in the art given the teachings herein.

Once the system has been notified of the change in operational mode, method 600 then proceeds to step 608. In step 608, the memory macro itself is changed to perform single-cell storage. For the case depicted in FIGS. 4A and 5, pseudo-differential sensing is also enabled. With reference to exemplary memory circuit 500 shown in FIG. 5, for example, latch 520 would output a logic low signal, thereby enabling the reference cells (e.g., cells 501r+, 501r−, 502r−, 502r+) in the memory subarrays (e.g., 550), which are utilized during single-cell operation. Once the memory macro has been configured to perform single-cell storage and pseudo-differential sensing, the change in operational mode to full capacity is complete in step 610. In step 610, an acknowledgment of such mode transition to full capacity mode may be generated.

Preserving state between transitions reduces energy consumption. When transitioning from half capacity to full capacity operational modes, at least three steps for a low energy transition are preferably followed, according to an embodiment of the invention. First, the twin-cell memory configuration must be driven to a voltage that is high enough for single-cell functionality. Next, all the memory cells operating as twin cells, are refreshed at the higher voltage. Finally, the memory is configured to operate in single-cell mode at full capacity. Half memory cells are now operative to store valid data. The other half of the memory cells, which served to store the complement state in the twin-cell configuration, are made available for use and thus can store new data as required subsequently by the system.

If, in step 604, it is determined that half capacity mode is desired, method 600 proceeds to step 612, wherein memory status queues (e.g., cache memory), etc., in the memory circuit are changed from full capacity functionality to half capacity functionality. Thus, step 612, as in step 606, functions to convey to the overall memory system architecture information which enables the system to adapt to the change in operational mode, since the manner in which the system stores data will change accordingly. In response, the system can then control the memory address space to adapt to the selected operational mode. Step 612 is also preferably operative to preserve memory state locally during the transition between operational modes.

Once the system has been notified of the change in operational mode, method 600 then proceeds to step 614. In step 614, the memory macro itself is changed to perform twin-cell storage. For the exemplary case depicted in FIGS. 4A and 5, differential sensing is also enabled. With reference again to exemplary memory circuit 500 shown in FIG. 5, for example, latch 520 would output a logic high signal, thereby disabling the reference cells (e.g., cells 501r+, 501r−, 502r−, 502r+) in the memory subarrays (e.g., 550), which are not utilized during twin-cell operation. Once the memory macro has been configured to perform twin-cell storage and differential sensing, the change in operational mode to half capacity is complete in step 616. In step 616, an acknowledgment of such mode transition to half capacity mode may be generated.

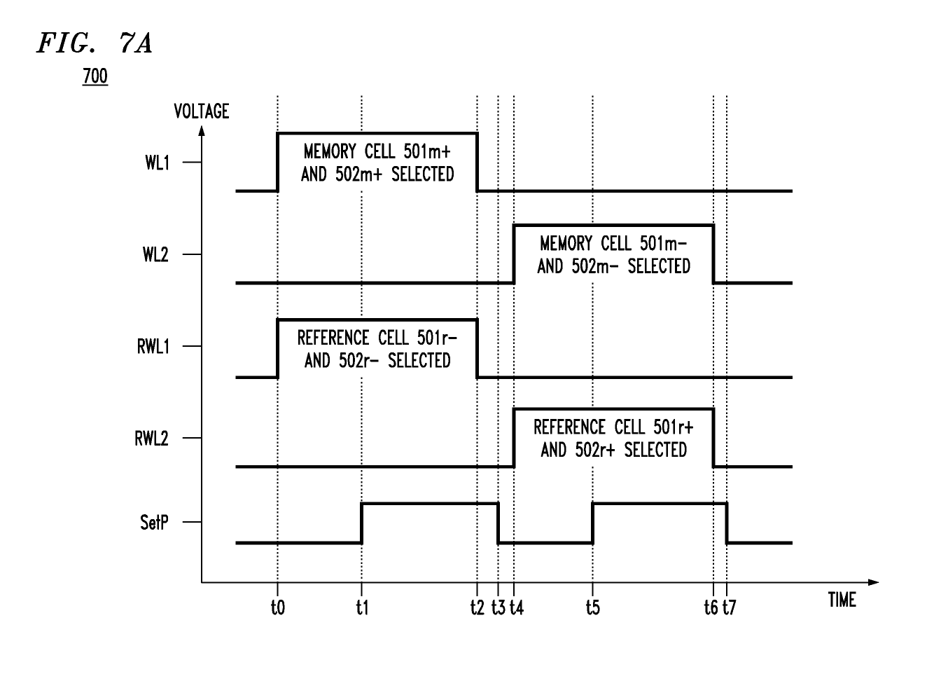

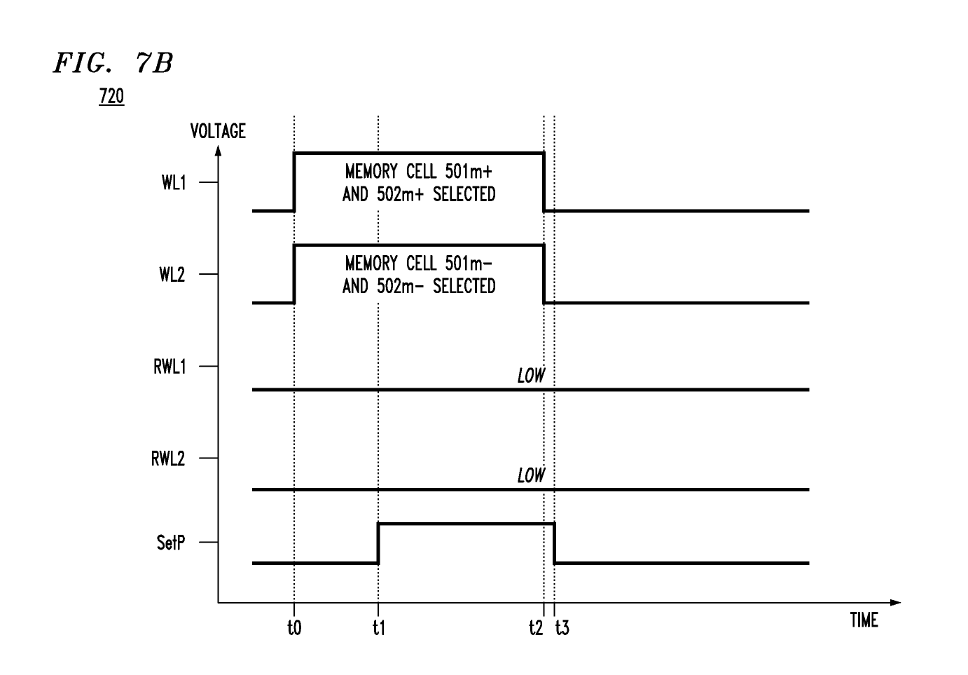

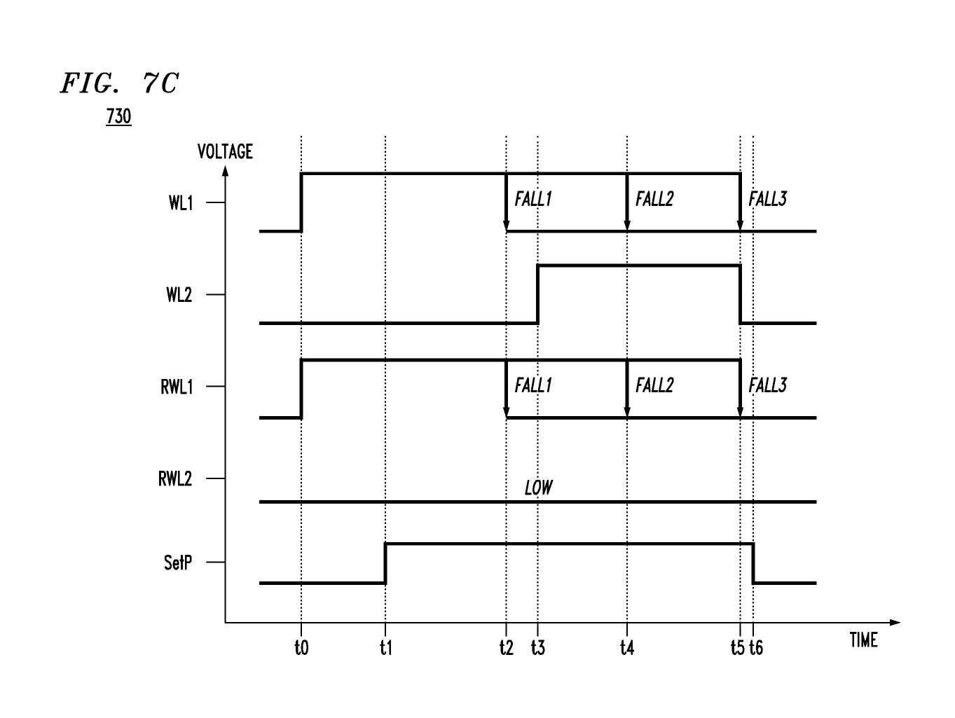

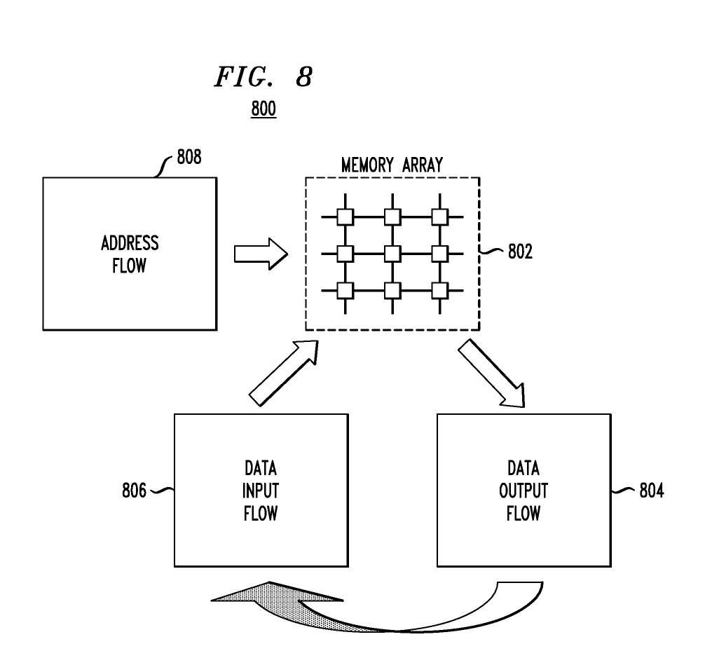

FIGS. 7A-7C are timing diagrams depicting exemplary waveforms corresponding to the memory circuit 500 shown in FIG. 5 during various operational modes of the memory circuit, according to embodiments of the invention. With reference to FIG. 7A, a timing diagram 700 depicts illustrative waveforms corresponding to a single-cell mode of operation of the exemplary memory array 500 shown in FIG. 5, according to an embodiment of the invention.

At time t0, word line WL1 and reference word line RWL1 are asserted (e.g., logic “1” or high level), thereby selecting memory cells 501m+ and 502m+ and reference cells 501r− and 502r−. Word line WL2 and reference word line RWL2 are at a logic low level, thereby disabling memory cells 501m− and 502m− and reference cells 501r+ and 502r+. At time t1, the SetP control signal is asserted (e.g., driven high), thereby latching the state on bit lines corresponding to selected memory cells to be read. As can be seen, activation of the SetP signal is delayed by a prescribed amount of time after selection of the memory cells to allow the selected memory cells to charge the voltage on the respective bit lines coupled to the selected memory cells to their corresponding states before the voltage is amplified by the sense amplifier. The amount of delay in assertion of the SetP signal after a memory cell has been selected will be a function of a measured intrinsic delay of the memory system, which is indicative of timing of the data settling on the bit lines. At time t2, word line WL1 and reference word line RWL1 are deasserted (e.g., logic “0” or low) to thereby disable the selected memory cells and reference cells. The SetP signal is then deasserted at time t3.

At time t4, word line WL2 and reference word line RWL2 are asserted (e.g., logic “1” or high level), thereby selecting memory cells 501m− and 502m− and reference cells 501r+ and 502r+. Word line WL1 and reference word line RWL1 remain at a logic low level, thereby disabling memory cells 501m+ and 502m+ and reference cells 501r− and 502r−. At time t5, the SetP control signal goes high (asserted) latching the state on bit lines corresponding to the selected memory cells to be read. As previously stated, activation of the SetP signal is delayed by a prescribed amount of time after selection of the memory cells to allow the selected memory cells to charge the voltage on the respective bit lines to their corresponding states before the voltage is amplified by the sense amplifier. At time t6, word line WL2 and reference word line RWL2 are deasserted (e.g., logic “0” or low) to thereby disable the selected memory cells and reference cells. The SetP signal is then deasserted at time t7.

With reference to FIG. 7B, a timing diagram 720 depicts illustrative waveforms in a twin-cell mode of operation of the exemplary memory array 500 shown in FIG. 5, according to an embodiment of the invention. At time t0, both word lines WL1 and WL2 are asserted, thereby selecting memory cells 501m+, 501m−, 502m+ and 502m−. After a prescribed delay, determined at least in part by one or more intrinsic properties of the memory circuit, the SetP signal is asserted at time t1, thereby latching the state of the bit lines corresponding to the selected memory cells. In the twin-cell (also referred to as dual-cell) mode or operation, the reference cells are preferably disabled. Consequently, reference word lines RWL1 and RWL2 are both deasserted (low). At time t2, the word lines WL1 and WL2 are deasserted, followed by deassertion of the SetP signal at time t3.

With reference to FIG. 7C, a timing diagram 730 depicts illustrative waveforms in a low-energy copy feature of the exemplary memory array 500 shown in FIG. 5 during a transition from single-cell to twin-cell storage, according to an embodiment of the invention. At time t0, word line WL1 and reference word line RWL1 are asserted (e.g., driven high), thereby selecting corresponding memory cells 501m+ and 502m+ and reference cells 501r− and 502r−. After a prescribed delay, determined at least in part by one or more intrinsic properties of the memory circuit, the SetP signal is asserted at time t1, thereby latching the state of the bit lines corresponding to the selected memory cells.

At time t2 or t4 or t5 (depending on prescribed design goals), word line WL1 and reference word line RWL1 are deasserted, thereby disabling the selected memory cells and reference cells from the corresponding bit lines. At time t3, word line WL2 is asserted, and the complement states of memory cells 501m+ and 502m+ immediately begin to be stored into memory cells 501m− and 502m−, respectively. At time t5, word lines WL1 and WL2 are deasserted, followed by deassertion of the SetP signal at time t6. It should be noted that the SetP signal ideally extends from time t1, when data is sensed from memory cells 501m+ and 502m+, through the duration of the writing of the complement of cell states into memory cells 501m− and 502m−. The differential sense amplifiers 504 and 506 source the charge both to restore the true states and to generate the complement states within the twin cells defined as the pair of memory cells 501m+ and 501m− and, likewise, the pair of memory cells 502m+ and 502m−.

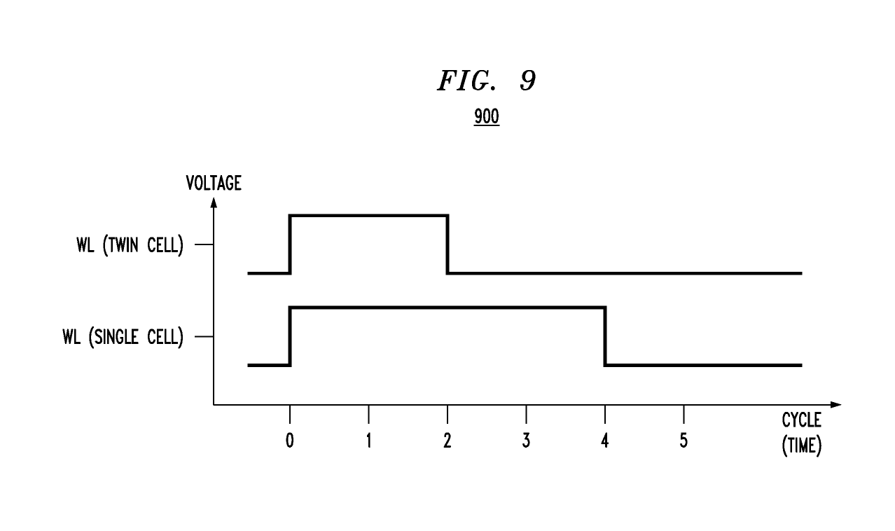

FIG. 8 is a block diagram conceptually illustrating at least a portion of an exemplary memory system 800 comprising a memory array 802 operative to reorganize memory advantageously for the system by circulating data within data and address flows 804, 806 and 808, respectively, and by storing the data in a new location(s) during a transition from full capacity to half capacity operational modes, according to an embodiment of the invention. As apparent from FIG. 8, data retrieved during intermediate reads of selected memory cells in a given address flow 808 may be at least temporarily stored in precharge circuits of a data output flow 804 for use in a special read-write operation, directed by the system 800, that reorganizes the memory in its transition from full capacity (single-cell) to half capacity (twin-cell) operational modes. During this operation, data may first be retrieved from the memory array 802 through the data output flow 804 as specified by a first address in the address flow 808. Next, the data may be driven into the data input flow 806. Finally, the data may be written back into the memory array 802 to a second (new) address selected through the address flow 808. Bits within the data are not modified during this memory reorganization.

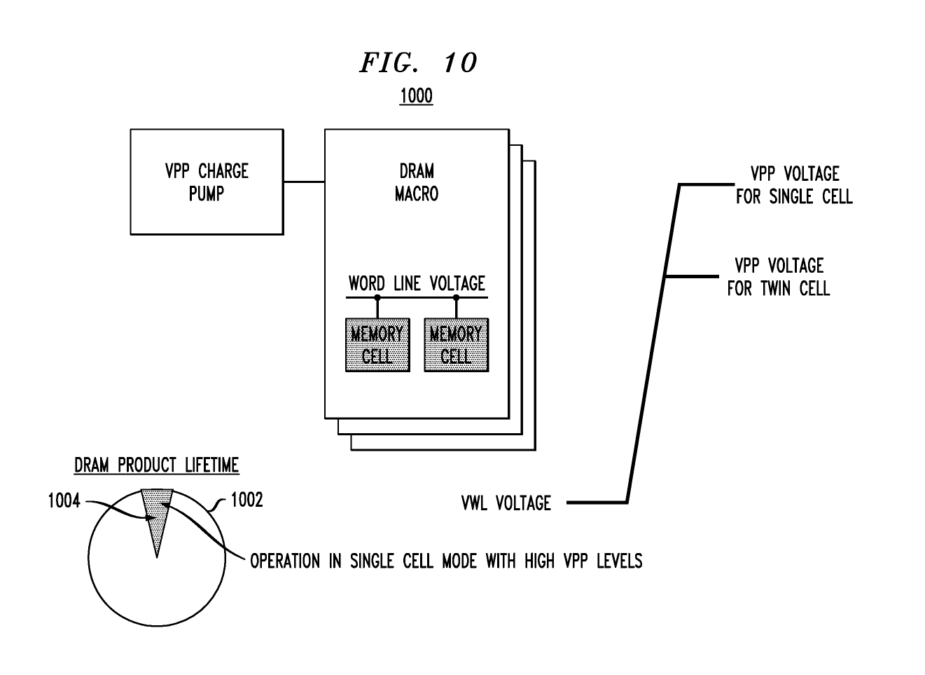

Referring now to FIG. 9, a timing diagram 900 depicts exemplary waveforms corresponding to a timing adjustment methodology for single-cell and twin-cell modes of operation, according to an embodiment of the invention. As shown, word line WL memory cycle timing for the single-cell mode of operation is preferably extended on-the-fly compared to word line memory cycle timing for the twin-cell mode of operation. In the illustrative case shown in FIG. 9, WL cycle timing for single-cell mode is about twice the cycle timing for twin-cell mode.

FIG. 10 is a block diagram depicting an exemplary methodology for adjusting word line voltage high level (VPP) for single-cell and twin-cell modes of operation, according to an embodiment of the invention. To store adequate charge in the N-type memory cells for state storage, the minimum word line voltage high level for the single-cell mode of operation is ideally always equal to or greater than the word line minimum high voltage level for the twin-cell mode of operation. The twin-cell stores twice the charge that the single-cells store so its internal node voltages do not need to be charged to the same level as the single cell.

Due to reliability constraints in practical designs, word line voltage often limits the voltage, and hence charge, stored on the internal node(s) of the memory cells. For such memory cells operated at elevated voltages beyond the reliability limits for long term operation, memory capacity per unit area could be expanded without loss of signal margin (i.e., greater storage) by increasing the number of memory cells connected to each of its constituent sense amplifiers (e.g., via corresponding bit lines). Robust operation could be achieved only for a limited period of time. If the memory circuit were to be continuously operated at this elevated voltage level, however, the total operating lifetime of the device would be significantly diminished. This is due primarily to increased likelihood of breakdown in the device as a result of the elevated operating voltage.

If operation of the memory device in single-cell mode, with its corresponding elevated word line voltage high level VPP, is constrained to only a small fraction of the total operating lifetime of the device, as depicted in FIG. 10, VPP levels for N-type single cells operating in full capacity mode can be advantageously increased (e.g., by about 150 millivolts) while still satisfying prescribed product reliability specifications. Once the maximum time period for reliable operation for single-cell storage has elapsed, the memory could be driven permanently into twin-cell mode of operation. Hence, the system would still function but at lower performance than in single-cell mode (typically).

With reference to FIG. 10, such a system 1000 preferably includes a timer 1002, or alternative controller, operative to accumulate or otherwise measure the time the memory operates in single-cell mode 1004. It should be understood that until a prescribed total time for reliable operation of the memory has been reached, the memory can be selectively switched back and forth between single-cell and twin-cell modes of operation, as explained in conjunction with the exemplary method 600 shown in FIG. 6. Once the prescribed total time has elapsed, the timer preferably informs the system 1000 to request one final change in operational mode to half capacity. Following steps 602, 604, 612, 614 and 616 of FIG. 6, the system and memory would thereby complete the transition to half capacity mode 616.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus (e.g., processor 310 shown in FIG. 3), or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures (e.g., FIGS. 3, 4A-4C, 5, 6, 8 and/or 10) illustrate at least a portion of the architecture, functionality, and/or operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be understood that, in some alternative implementations, the functions noted in a given block or blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

At least a portion of the techniques of the present invention may be implemented in one or more integrated circuits. As is known in the art, integrated circuits comprise semiconductor structures. Such semiconductor structures may comprise a substrate and circuits formed within or upon the substrate, for example, one or more word line driver circuits or DRAM circuits in accordance with the invention. In forming integrated circuits, die are typically fabricated in a repeated pattern on a surface of a semiconductor wafer. Individual die are cut or diced from the wafer, then packaged as integrated circuits. One skilled in the art would know how to dice wafers and package die to produce integrated circuits. Integrated circuits so manufactured are considered part of this invention. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip may then be integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

An integrated circuit in accordance with techniques of the present invention can be employed in conjunction with essentially any apparatus, application and/or electronic system which utilizes memory, particularly DRAM, either embedded or discrete. Suitable systems for implementing the invention may include, but are not limited to, personal computers, communication networks, electronic commerce systems, portable communications devices (e.g., cell phones), solid-state media storage devices, etc. Systems incorporating such integrated circuits are considered part of this invention.

Although illustrative embodiments of the invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A memory circuit, comprising:
a memory array including a plurality of memory cells, a plurality of word lines, and at least a first bit line, each of the plurality of memory cells being coupled to a unique pair of a bit line and a word line for selectively accessing the memory cells; and
at least one control circuit coupled to the word lines and being operative to selectively change an operation of the memory array between a first data storage mode and at least a second data storage mode as a function of at least one control signal supplied to the control circuit, wherein in the first data storage mode, each of the memory cells is allocated to a corresponding stored logic bit, and in the second data storage mode, at least two memory cells are allocated to a corresponding stored logic bit.

2. The memory circuit of claim 1, wherein the at least one control circuit is operative: (i) to receive a request for a change in data storage mode of the memory array; (ii) to determine whether the first data storage mode indicative of a full capacity state or at least the second data storage mode indicative of a half capacity state is selected; (iii) to change memory status queues in the memory circuit to one of full capacity state and half capacity state as a function of the selected data storage mode, whereby the memory circuit is operative to control an address space of the memory array to adapt to the selected data storage mode; and (iv) to adapt the memory array to operate in the selected data storage mode.

3. The memory circuit of claim 1, wherein the at least one control circuit is operative to preserve a state of the memory array during a transition between the first data storage mode and the at least second data storage mode.

4. The memory circuit of claim 3, wherein in preserving the state of the memory array, the control circuit is operative to perform at least one of storing local data in another prescribed location in the memory circuit, rearranging data in the memory array, and declaring local data in the memory array invalid.

5. The memory circuit of claim 1, further comprising at least one sensor coupled to the at least one control circuit, the at least one sensor being operative to detect one or more characteristics of the memory circuit and to generate the at least one control signal as a function of one or more detected characteristics.

6. The memory circuit of claim 1, wherein the at least one control signal is indicative of one or more characteristics of the memory circuit.

7. The memory circuit of claim 6, wherein the one or more characteristics of the memory circuit comprise at least one of process, supply voltage and temperature (PVT) variations of the memory circuit.

8. The memory circuit of claim 1, further comprising:
at least one differential sense amplifier including a first input coupled to a first subset of the plurality of memory cells and a second input coupled to a second subset of the plurality of memory cells; and
at least first and second reference cells coupled to the first and second inputs, respectively, of the sense amplifier, the first and second reference cells being operative to assist in evaluation of data states stored in selected memory cells coupled to the sense amplifier;
wherein the at least one control circuit is operative during the second data storage mode to disable the at least first and second reference cells.

9. The memory circuit of claim 8, wherein the at least one sense amplifier is operative to perform pseudo-differential sensing in the first data storage mode and is operative to perform differential sensing in the second data storage mode.

10. The memory circuit of claim 1, wherein the at least one control circuit is connected in an address decode path of the memory circuit.

11. A memory circuit for use in a processing system, comprising:
a memory array including a plurality of memory cells, at least one bit line, and at least two word lines, each memory cell being coupled to a unique pair of a bit line and a word line, each word line being adapted for accessing at least one of two memory cells connected to the at least one bit line;
a first control circuit operative to enable one of the word lines in a first operational mode of the memory circuit and to enable at least two of the word lines in a second operational mode of the memory circuit; and
a second control circuit operative to adapt the processing system to selectively transition at least a portion of the memory array between the first and second operational modes;
wherein in the first operational mode, each of the memory cells is allocated to a corresponding stored logic bit, and in the second operational mode, at least two memory cells are allocated to a corresponding stored logic bit.

12. The memory circuit of claim 11, wherein the second control circuit is operative: (i) to receive a request for a change in operational mode of the memory array; (ii) to determine whether the first operational mode indicative of a full capacity state or the second operational mode indicative of a half capacity state is selected; (iii) to change memory status queues in the memory circuit to one of full capacity state and half capacity state as a function of the selected operational mode, whereby the memory circuit is operative to control an address space of the memory array to adapt to the selected operational mode; and (iv) to adapt the memory array to operate in the selected operational mode.

13. The memory circuit of claim 11, wherein the second control circuit is operative to preserve a state of the memory array during a transition between the first and second operational modes.

14. The memory circuit of claim 13, wherein in preserving the state of the memory array, the second control circuit is operative to perform at least one of storing local data in another prescribed location in the memory circuit, rearranging data in the memory array, and declaring local data in the memory array invalid.

15. The memory circuit of claim 11, wherein the second control circuit is operative to adapt the processing system to selectively transition at least a portion of the memory array between the first and second operational modes as a function of one or more characteristics of the memory circuit.

16. The memory circuit of claim 15, wherein the one or more characteristics of the memory circuit comprise at least one of process parameters, supply voltage and temperature (PVT) variations of the memory circuit.

17. The memory circuit of claim 11, further comprising:
at least one differential sense amplifier including a first input coupled to a first subset of the plurality of memory cells and a second input coupled to a second subset of the plurality of memory cells; and
at least first and second reference cells coupled to the first and second inputs, respectively, of the sense amplifier, the first and second reference cells being operative to assist in evaluation of data states stored in selected memory cells coupled to the sense amplifier;
wherein the first control circuit is operative during the second operational mode to disable the at least first and second reference cells.

18. The memory circuit of claim 11, wherein the first control circuit is connected in an address decode path of the memory circuit.

19. A circuit for use in conjunction with a dynamic random access memory (DRAM) comprising at least one differential sense amplifier and a memory array including a plurality of memory cells and at least first and second word lines coupled to the memory cells, the first word line being operative for selectively accessing a first one of the memory cells coupled to a first input of the sense amplifier and the second word line being operative for selectively accessing a second one of the memory cells coupled to a second input of the sense amplifier, the circuit comprising:
a first controller coupled to the memory array and operative, during a given memory cycle, to selectively enable one word line in a first operational mode of the circuit or to selectively enable at least two word lines in at least a second operational mode of the circuit; and
a second controller operative to adapt the DRAM to operate with the memory array in the first and second operational modes.

20. The circuit of claim 19, wherein in the first operational mode, each of the memory cells is allocated to a corresponding stored logic bit, and in the at least second operational mode, at least two memory cells are allocated to a corresponding stored logic bit.

21. The circuit of claim 19, wherein the first controller comprises:
a latch operative to determine whether the DRAM is operative in one of at least the first operational mode, wherein each of the memory cells in the memory array is allocated to a corresponding stored logic bit, and the second operational mode, wherein at least two memory cells in the memory array are allocated to a corresponding stored logic bit; and
first and second functional OR gates coupled to the latch, the first functional OR gate being connected in a first address decode path and operative to receive a first address signal supplied to the circuit, the second functional OR gate being connected in a second address path and operative to receive a second address signal supplied to the circuit;
wherein the latch, in conjunction with the first and second functional OR gates, are operative to selectively enable one of the first and second word lines in the first operational mode as a function of the first and second address signals, respectively, and to selectively enable the first and second word lines in the second operational mode.

22. The circuit of claim 21, wherein the DRAM further comprises at least first and second reference cells coupled to the first and second inputs, respectively, of the sense amplifier, the first and second reference cells being operative to assist in evaluation of data states stored in selected memory cells coupled to the sense amplifier, and wherein the latch is further operative during the second operational mode to disable the at least first and second reference cells

23. A method for dynamically transitioning a memory circuit between a first data storage mode and at least a second data storage mode, the memory circuit comprising at least one differential sense amplifier and a memory array including a plurality of memory cells and at least first and second word lines coupled to the memory cells, the first word line being operative for selectively accessing a first one of the memory cells coupled to a first input of the sense amplifier and the second word line being operative for selectively accessing a second one of the memory cells coupled to a second input of the sense amplifier, the method comprising the steps of:
receiving a request for a change in data storage mode of the memory array;
determining whether the memory circuit is operative in one of at least a first data storage mode indicative of a full capacity state, wherein each of the memory cells in the memory array is allocated to a corresponding stored logic bit, and a second data storage mode indicative of a half capacity state, wherein at least two memory cells in the memory array are allocated to a corresponding stored logic bit; and
changing memory status queues in the memory circuit to one of at least full capacity and half capacity states as a function of the selected data storage mode.

24. The method of claim 22, further comprising the steps of:
controlling an address space of the memory array to adapt to the selected data storage mode; and
adapting the memory array to operate in the selected data storage mode.

25. A computer program product for dynamically transitioning a memory circuit between a first data storage mode and at least a second data storage mode, the memory circuit comprising a memory array including a plurality of memory cells and at least first and second word lines coupled to the memory cells for selectively accessing one or more of the memory cells, the computer program product comprising:
a computer readable storage medium;
first program instructions to receive a request for a change in data storage mode of the memory array;
second program instructions to determine whether the memory circuit is operative in one of at least a first data storage mode indicative of a full capacity state, wherein each of the memory cells in the memory array is allocated to a corresponding stored logic bit, and a second data storage mode indicative of a half capacity state, wherein at least two memory cells in the memory array are allocated to a corresponding stored logic bit; and
third program instructions to change memory status queues in the memory circuit to one of at least full capacity and half capacity states as a function of the selected data storage mode;
wherein the first, second and third program instructions are stored on said computer readable storage medium.
